(19) United States
(12) Patent Application Publication
(10) Pub. No.: US 2020/0111926 A1
(43) Pub. Date: Apr. 9, 2020

(54) SOLAR PHOTOVOLTAIC SYSTEM

(71) Applicant: INDUSTRIAL TECHNOLOGY RESEARCH INSTITUTE, Hsinchu (TW)

(72) Inventors: Ren-Chin SHR, Hsinchu City (TW); Jhong-Yuan WANG, Tainan City (TW); Hao-Min CHAN, Hsinchu City (TW); Hsiang-Ying CHENG, Kaohsiung City (TW)

(73) Assignee: INDUSTRIAL TECHNOLOGY RESEARCH INSTITUTE, Hsinchu (TW)

(21) Appl. No.: 16/217,562

(22) Filed: Dec. 12, 2018

(30) Foreign Application Priority Data
Oct. 3, 2018 (TW) 107134904

(51) Int. Cl. H01L 31/044; H01L 31/02; H02S 40/34; H02S 50/10; H05B 33/08; H01L 31/0224

(52) U.S. Cl. CPC H01L 31/044; H01L 31/02008; H01L 31/022425; H02S 50/10; H05B 33/0806; H02S 40/34

(57) ABSTRACT

A solar photovoltaic system includes a solar cell array, a bypass diode and a light-emitting module. The solar cell array has a positive terminal and a negative terminal and includes a plurality of solar cells connected in series. The bypass diode is connected to the solar cell array in parallel. The light-emitting module is connected to the solar cell array in parallel and includes a Zener diode and a light-emitting diode. The Zener diode has a cathode and an anode electrically connected to the positive terminal and the negative terminal of the solar cell array, respectively. The light-emitting diode is connected to the Zener diode in series. The light-emitting module has a threshold voltage which is a breakdown voltage of the Zener diode and related to a voltage of a maximum power of the solar cell array under a standard illuminance.

### CROSS REFERENCE TO RELATED APPLICATION

This application claim the priority benefit of Taiwan application serial no. 107134904, filed on Oct. 3, 2018. The entirety of the above-mentioned patent application is hereby incorporated by reference herein.

### TECHNICAL FIELD

The technical field generally relates to solar photovoltaic system.

### BACKGROUND

In a solar power generation array, failure of a single module will cause the overall power generation to drop, or even fail to work properly and supply power. Most of solar energy farms have a serial monitoring system, however, when an abnormality occurs in a battery array, it is not easy to find out which module is abnormal. So that the user can hardly perform the real-time monitoring in a quick way, and immediately find the location of the faulty module.

When a module monitoring and a module integration need to be certified, the cost is relatively increased because of extremely high reliability requirements. Therefore, how to monitor solar modules in a fast, simple and low-cost manner is an important issue.

### SUMMARY OF THE DISCLOSURE

This disclosure provides a solar photovoltaic system which utilizes the characteristics of the Zener diode to determine the degree of failure of the solar cell array.

According to an embodiment of the disclosure, a solar photovoltaic system includes a solar cell array, a bypass diode and a light-emitting module. The solar cell array has a positive terminal and a negative terminal, and includes a plurality of solar cells connected in series. The bypass diode is connected to the solar cell array in parallel. The light-emitting module is connected to the solar cell array in parallel and includes a Zener diode and a light-emitting diode. The Zener diode has an anode and a cathode. The cathode and the anode are electrically connected to the positive terminal and the negative terminal of the solar cell array, respectively. The light-emitting diode is connected to the Zener diode in series. The light-emitting module has a threshold voltage which is a breakdown voltage of the Zener diode and related to a voltage of a maximum power of the solar cell array under a standard illuminance.

According to an embodiment of the disclosure, a solar photovoltaic system includes a solar photovoltaic module and a light-emitting module. The solar photovoltaic module has a positive terminal a negative terminal, and includes a plurality of solar cell arrays and a plurality of bypass diodes. Each bypass diode is connected to a corresponding solar cell array of the solar cell arrays in parallel. The light-emitting module is connected to the solar photovoltaic module in parallel. The light-emitting module includes a Zener diode and a light-emitting diode. The Zener diode has an anode and a cathode, the cathode is electrically connected to the positive terminal of the solar photovoltaic module, and the anode is electrically connected to the negative terminal of the solar photovoltaic module. The light-emitting diode is electrically connected to the Zener diode is series. The light-emitting module has a threshold voltage which is a breakdown voltage of the Zener diode and is less than a voltage of a maximum power of the solar cell arrays under a test condition.

According to an embodiment of this disclosure, a solar photovoltaic system includes a plurality of solar cell arrays, a plurality of bypass diodes and a plurality of light-emitting modules. Each solar cell array has a positive terminal and a negative terminal, and has a plurality of solar cells connected to each other in series. Each bypass diode is connected to a corresponding solar cell array of the solar cell arrays in parallel. Each light-emitting module is connected to a corresponding solar cell array of the solar cell arrays in parallel. Each light-emitting module comprises a Zener diode and a light-emitting diode. The Zener diode has an anode and a cathode. The cathode of the Zener diode is electrically connected to the positive terminal of the corresponding solar cell array while the anode of the Zener diode is electrically connected to the negative terminal of the corresponding solar cell array. The light-emitting diode is connected to the Zener diode in series. The light-emitting module has a threshold voltage which is a breakdown voltage of the Zener diode and is related to a voltage of a maximum power of the solar cell array under a standard illuminance.

In summary, this disclosure provides a solar photovoltaic system in which a voltage of a maximum power of the solar cell array under a standard illuminance is analyzed to select an appropriate Zener diode. The Zener diode combined with a light-emitting diode is configured in a solar cell module. By utilizing the characteristics of the Zener diode, the light-emitting diode illuminates by selectively turning on the circuit according to the voltage provided by the solar cell module, thereby achieving failure detection of the solar cell module.

The foregoing will become better understood from a careful reading of a detailed description provided herein below with appropriate reference to the accompanying drawings

### BRIEF DESCRIPTION OF THE DRAWINGS

FIG. 1 shows a circuit diagram of a solar photovoltaic system according to an embodiment of this disclosure.

FIG. 2 is a schematic diagram of voltage-current curves of a solar module according to an embodiment of the disclosure.

FIG. 3 is a schematic circuit diagram of a solar photovoltaic system according to an embodiment of the present disclosure.

FIG. 4 is a schematic circuit diagram of a solar photovoltaic system according to another embodiment of the present disclosure.

FIG. 5 is a schematic circuit diagram of a solar photovoltaic system according to another embodiment of the present disclosure.

FIG. 6 is a schematic circuit diagram of a solar photovoltaic system according to yet another embodiment of the present disclosure.

FIG. 7 is a schematic circuit diagram of a solar photovoltaic system according to yet another embodiment of the present disclosure.

### DETAILED DESCRIPTION OF DISCLOSED EMBODIMENTS

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

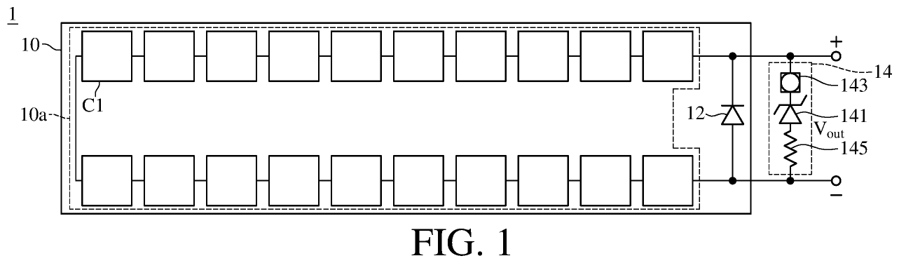

Referring to FIG. 1, FIG. 1 shows a circuit diagram of a solar photovoltaic system according to an embodiment of this disclosure. As shown in FIG. 1, the solar photovoltaic system 1 comprises a solar cell array 10a, a bypass diode 12 and a light-emitting module 14. The solar cell array 10a is composed of a plurality of solar cells C1 connected in series and is combined with the bypass diode 12 as a solar cell module 10. These solar cells C1 can convert incident sunlight into electrical energy, thereby providing an operating voltage Vout. The number of solar cells in this embodiment is for illustrative purposes only, but the invention of the disclosure is not limited thereto. Each of the bypass diode 12 and the light-emitting module 14 is connected to the solar cell array 10a in parallel. The light-emitting module 14 comprises a Zener Diode 141 and a light-emitting diode 143. The Zener diode 141 has an anode and a cathode. The cathode and the anode of the Zener diode are electrically connected to the positive terminal (+) and the negative terminal (−) of the solar cell array 10a, respectively. The light-emitting diode 143 is connected to the Zener diode 141 in series.

The light-emitting module has a threshold voltage. The solar photovoltaic system 1 selectively turns on the system loop according to the operating voltage Vout and the threshold voltage to make the light-emitting diode 143 illuminate, thereby determining whether the solar cell C1 is abnormal or not. More specifically, the threshold voltage could be seen as a breakdown voltage of the Zener diode 141. The solar photovoltaic system 1 of this disclosure utilizes the characteristics of the breakdown voltage of the Zener diode 141 to perform an internal failure detection of the solar cell module.

An exemplary embodiment is given below for further illustration, assuming that the breakdown voltage of the Zener diode 141 is 6 volts. While the solar cells C1 inside the solar module are all in a normal state, since the output operating voltage Vout is large enough, a reverse bias voltage reaching the value of the breakdown voltage can be provided to turn on the Zener diode 141, thereby making the light-emitting diode 143 illuminate. Conversely, when the solar cell C1 inside the solar module is in an abnormal state (for example, object blocking or hot spot effect), the output operating voltage Vout becomes smaller. Therefore, the reverse bias voltage provided fails to reach the value of the breakdown voltage so that the Zener diode 141 cannot be turned on. At the moment, the light-emitting diode 143 fails to illuminate.

The breakdown voltage is related to a voltage of a maximum power of the solar cell array under a test condition. Specifically, the breakdown voltage is less than a maximum power point voltage under the test condition. For example, a relation of 0.25 Vmpp<Vb<Vmpp can be obtained, where the breakdown voltage is denoted as Vb, and the maximum power point voltage under the test condition is denoted as Vmpp. In detail, the breakdown voltage of the Zener diode 141 is selected mainly by measuring the maximum power point voltage of different illuminance levels for the solar cell array 10a under the test condition (for example, a standard test condition). A regression equation is found by using a least square method to perform the linear regression analysis for different maximum power points. Then, the reverse-transmission voltage specification (that is, the breakdown voltage) of the Zener diode 141 is defined by using this regression equation and taking a voltage difference into account, where the voltage difference is caused by the temperature difference between the actual operation of the solar module and the standard test condition of the solar module. In practice, the standard test condition (STC) of the ground photovoltaic module may refers to the atmospheric quality AM=1.5; the illuminance=1000 W/m2; and the temperature=25° C.

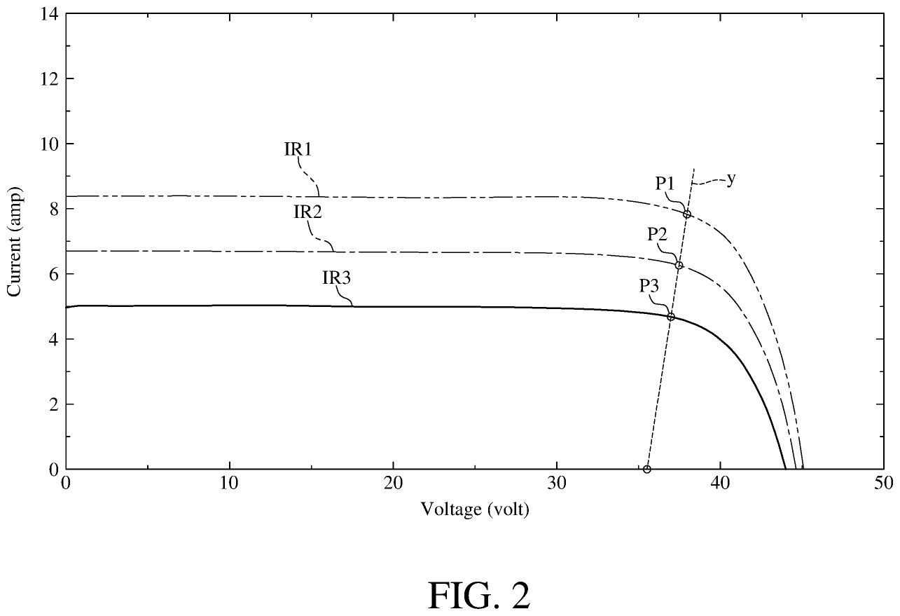

For example, please refer to FIG. 2, which is a schematic diagram of voltage-current curves of a solar module according to an embodiment of the disclosure. FIG. 2 shows the voltage-current curves of the solar module under different illuminances such as IR1˜IR3 under a test condition (25° C.), where the three voltage-current curves contain three maximum power points P1, P2, and P3, respectively. In this embodiment, the three illuminances IR1 to IR3 are 1000 W/m2, 800 W/m2, and 600 W/m2, respectively, and the three maximum power points P1 to P3 are (38, 7.8), (37.4, 6.2), (37, 4.8), respectively. A regression equation y is obtained by performing linear regression analysis for the three maximum power points P1 to P3. For example, a prediction model y=ax+b of the linear regression method can be used to obtain the solutions of a and b by substituting the three maximum power points P1 to P3 with (38, 7.8), (37.4, 6.2), and (37, 4.8), respectively. Accordingly, the regression equation y=2.973x−105.12 is obtained. By using this regression equation y, the preliminary Zener diode specification can be found. That is, the corresponding voltage (35.3V) is the preliminary Zener diode specification when the current is zero (y=0).

However, the normal operating temperature of the solar module will not keep at 25° C. When the module temperature is higher, the voltage will be lower. Therefore, the voltage difference caused by the temperature needs to be taken into consideration. This voltage difference is equal to V×Coev×(NOCT−STC), where V represents the module open circuit voltage, Coev represents the voltage temperature coefficient, NOCT represents the actual operating temperature, and STC represents the normal operating temperature. With the above-mentioned equation, the voltage difference can be obtained, which is 36×0.00416×(45−25)=2.99 (V). The final Zener diode specification (that is, 32.3V) can be defined by subtracting the voltage difference (that is, 2.99V) from the preliminary Zener diode specification (that is, 35.3V). In an exemplary embodiment, as shown in FIG. 1, the light-emitting module 14 further includes a current-limiting resistor 145. The current-limiting resistor 145 is connected in series with the light-emitting diode 143. Configuring the current-limiting resistor 145 is to limit the current that passes through the light-emitting diode 143 to prevent the light-emitting diode 143 from being damaged due to the excessive current.

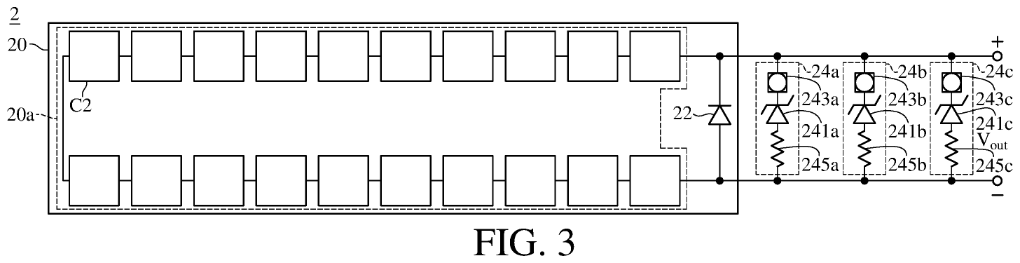

Please refer to FIG. 3. FIG. 3 is a schematic circuit diagram of a solar photovoltaic system according to an embodiment of the present disclosure. Comparing with the solar photovoltaic system 1 of the embodiment of FIG. 1, the solar photovoltaic system 2 shown in FIG. 3 includes a plurality of light-emitting modules. In detail, the solar photovoltaic system 2 includes a solar cell array 20a having a plurality of solar cells C2, a bypass diode 22, and light-emitting modules 24a, 24b, and 24c, wherein the solar cell array 20a and the bypass diode 22 constitute a solar module 20. The bypass diode 22 and the light-emitting modules 24a, 24b, and 24c are connected in parallel with the solar cell array 20a. The light-emitting module 24a includes a Zener diode 241a and a light-emitting diode 243a. The light-emitting module 24b includes a Zener diode 241b and a light-emitting diode 243b. The light-emitting module 24c includes a Zener diode 241c and a light-emitting diode 243c. The cathodes of the Zener diode 241a, the Zener diode 241b, and the Zener diode 241c are electrically connected to the positive terminal (+) of the solar cell array 20a. The anodes of the Zener diode 241a, the Zener diode 241b, and the Zener diode 241c are electrically connected to the negative terminal (−) of the solar cell array 20a. The number of the light-emitting modules described herein is for illustrative purposes only. In other embodiments, the number of the light-emitting modules may be, but not limited to, two or more than three.

In the embodiment of FIG. 3, each of the light-emitting modules 24a, 24b, and 24c individually has a threshold voltage representing the breakdown voltage of the corresponding Zener diodes 241a, 241b, and 241c, respectively. The breakdown voltages of these Zener diodes 241a, 241b, and 241c are all different, which are, for example, 6 volts, 9 volts, and 12 volts, respectively. In the embodiment of FIG. 3, Zener diodes with different specifications are used to detect the degree of failure of these solar cells C1 inside the solar module. For example, it is assumed that the breakdown voltages of the Zener diodes 241a, 241b, and 241c are 6 volts, 9 volts, and 12 volts, respectively. When the solar cell C1 inside the solar module is slightly abnormal, the output operating voltage Vout drops. Therefore, the reverse bias voltage provided is greater than 9 volts but less than 12 volts. At the moment, only the Zener diodes 241a and 241b are turned on to make the corresponding light-emitting diodes 243a and 243b illuminate. Since the Zener diode 241c is not turned on, the corresponding light-emitting diode 243c fails to illuminate.

According to another embodiment, when the solar cell C1 inside the solar module is severely abnormal, the reverse bias voltage provided is less than 6 volts. At the moment, all of the Zener diodes 241a, 241b, and 241c are not turned on, and thus the corresponding light-emitting diodes 243a, 243b, and 243c would not illuminate. In other words, the user could determine the degree of failure of the solar module according to the display of the light-emitting diode. In practice, the light-emitting diodes 243a, 243b, and 243c can emit light of different colors, such as green, yellow, red, and the like. The display of the different colors of the light-emitting diodes allows the user to quickly realize the current degree of failure of the solar module.

In practical applications, for large-scale solar photovoltaic systems (such as large-scale solar farms), the status of the light-emitting diodes in the solar photovoltaic system can be photographed using a drone to facilitate rapid detection. For small-scale solar photovoltaic systems (such as small rooftop solar farms), users can directly observe the light-emitting diodes, and then determine the system module's condition without reading related information of the system module. In an embodiment, each of the light-emitting modules 24a, 24b, and 24c has current-limiting resistors 245a, 245b, and 245c connected respectively in series with the light-emitting diodes 243a, 243b, and 243c for respectively limiting the currents of the light-emitting diodes 243a, 243b, and 243c to prevent the light-emitting diodes from being damaged due to excessive current.

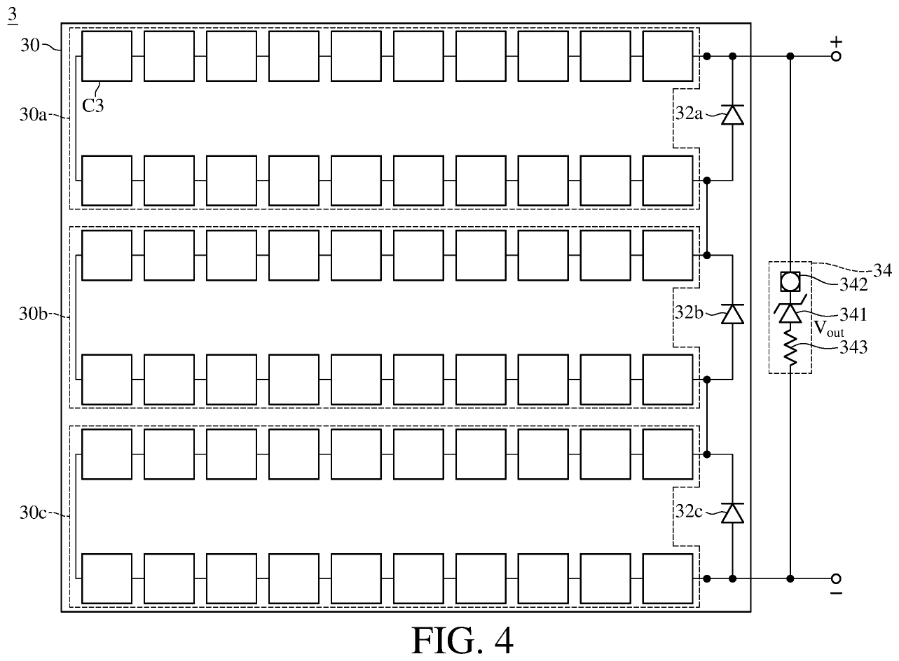

Please refer to FIG. 4. FIG. 4 is a schematic circuit diagram of a solar photovoltaic system according to another embodiment of the present disclosure. The solar photovoltaic system 3 shown in the embodiment of FIG. 4 includes a solar module 30 and a light-emitting module 34. Comparing with the embodiment of FIG. 1, the solar module 30 shown in FIG. 4 has a plurality of solar cell arrays 30a, 30b, and 30c and a plurality of bypass diodes 32a, 32b, and 32c. Each of the solar cell arrays has a plurality of solar cells C3 and is connected in parallel with corresponding bypass diodes. The light-emitting module 34 includes a Zener diode 341 and a light-emitting diode 342 which are connected in series. In practice, providing a bypass diode is to direct current to other cell arrays for keeping the operating of solar cell arrays without passing through the abnormal cell arrays when an abnormal situation (for example, hot spot effect) is happening to the solar cell arrays.

The positive terminal (+) and the negative terminal (−) of the solar module 30 are electrically connected to the cathode and the anode of the Zener diode 341 in the light-emitting module 34, respectively. Each of these solar cell arrays 30a, 30b, and 30c is formed by a plurality of solar cells C3 to provide an operating voltage Vout. Similar to the embodiment of FIG. 1, when the solar cell C3 inside the solar module 30 is abnormal, the operating voltage Vout provided is lower than the breakdown voltage of the Zener diode 341. At the moment, the Zener diode 341 fails to be turned on to make the light-emitting diode 342 illuminate. In an embodiment, the light-emitting module 34 further includes a current-limiting resistor 343 connected in series with the light-emitting diode 342 for limiting the current that passes through the light-emitting diode.

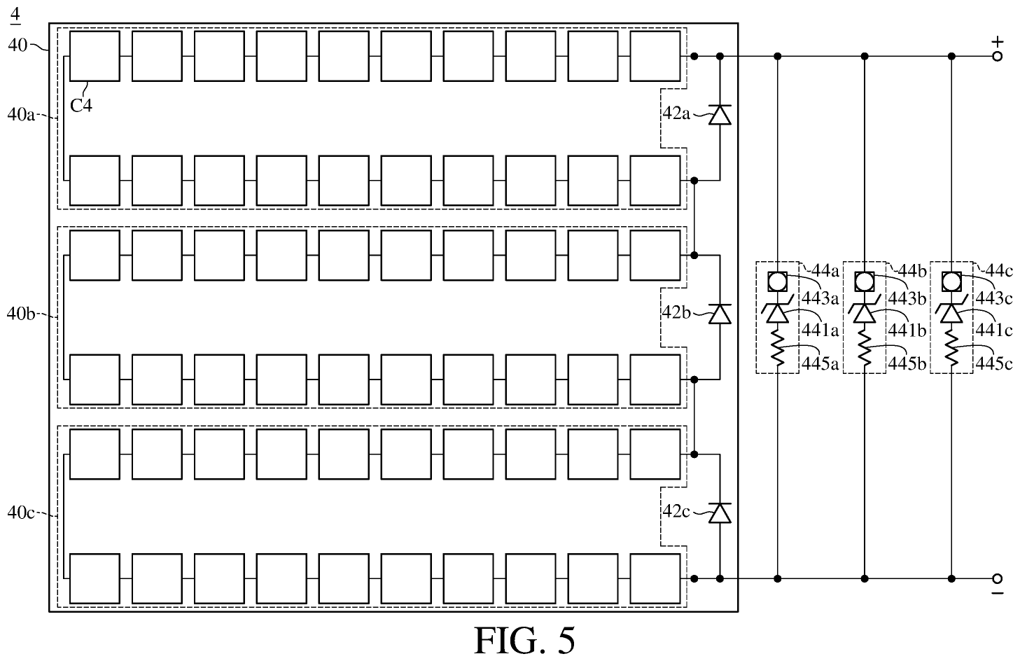

Please refer to FIG. 5. FIG. 5 is a schematic circuit diagram of a solar photovoltaic system according to another embodiment of the present disclosure. Comparing with FIG. 4, the solar photovoltaic system 4 in FIG. 5 is provided with a plurality of light-emitting modules. As shown in FIG. 5, the solar photovoltaic system 4 includes a solar module 40 and light-emitting modules 44a, 44b, and 44c. The solar module 40 has a plurality of solar cell arrays 40a, 40b, and 40c and a plurality of bypass diodes 42a, 42b, and 42c. Each solar cell array has a plurality of solar cells C4 connected with the corresponding bypass diodes in parallel. The light-emitting module 44a includes a Zener diode 441a and a light-emitting diode 443a connected in series with each other. The light-emitting module 44b includes a Zener diode 441b and a light-emitting diode 443b connected in series with each other. The light-emitting module 44c includes a Zener diode 441c and a light-emitting diode 443c connected in series with each other.

The plurality of light-emitting modules described above individually have threshold voltages representing the breakdown voltages of the corresponding Zener diodes 441a, 441b, and 441c, respectively. The breakdown voltages of these Zener diodes 441a, 441b, and 441c are all different. By utilizing the component characteristics of the specific breakdown voltage of the different specifications of the Zener diode, the overall failure state of the solar module can be effectively determined. When the solar cells among the solar cell arrays 40a, 40b, and 40c are abnormal, the supplied operating voltage Vout is lowered, resulting in insufficient reverse bias voltage supplied to the Zener diodes 441a, 441b, and 441c. Under the situation, only some of the Zener diodes are turned on or none of the Zener diodes is turned on. The degree of failure of the solar module can be easily detected by the states of the light-emitting diodes.

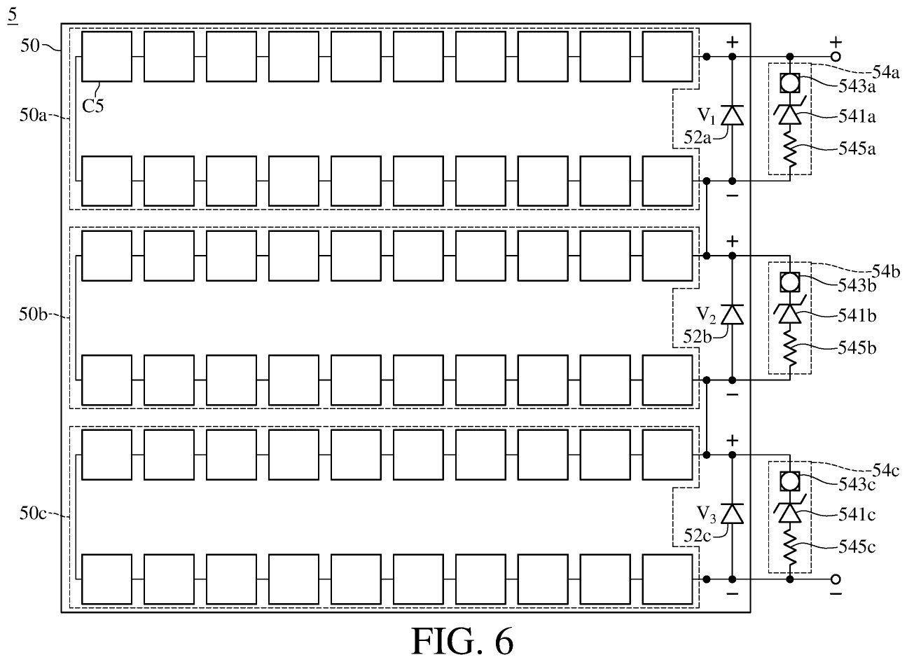

In the embodiments described above, a plurality of solar cell arrays share a set of light-emitting module. However, in order to more clearly present the failure state and degree of each solar cell array in the solar module, each of the solar cell arrays can be individually configured with a light-emitting module. For example, please refer to FIG. 6. FIG. 6 is a schematic circuit diagram of a solar photovoltaic system according to another embodiment of the present disclosure. As shown in FIG. 6, the solar photovoltaic system 5 includes a solar module 50 and a plurality of light-emitting modules 54a, 54b, and 54c. The solar module 50 includes a plurality of solar cell arrays 50a, 50b, and 50c and a plurality of bypass diodes 52a, 52b, and 52c. The light-emitting modules 54a, 54b, and 54c include Zener diodes 541a, 541b, and 541c and light-emitting diodes 543a, 543b, and 543c, respectively. Each solar cell array is connected in parallel with a corresponding bypass diode and a corresponding light-emitting module, and individually provides output voltages V1, V2, and V3. The solar cell arrays 50a, 50b, and 50c have their positive terminals and negative terminals electrically connected to the cathodes and the anodes of the Zener diodes 541a, 541b, and 541c, respectively.

In the embodiment of FIG. 6, each of the solar cell arrays is provided with its respective light-emitting module. The light-emitting modules 54a, 54b, and 54c have threshold voltages corresponding to the breakdown voltages of the Zener diodes 541a, 541b, and 541c, respectively. The breakdown voltage is associated with a voltage of a maximum power of the corresponding solar cell array under the standard illuminance condition. In detail, the breakdown voltages of the Zener diodes 541a, 541b, and 541c are associated with the voltages of the maximum powers of the solar cell arrays 50a, 50b, and 50c under the standard illuminance, respectively. A detailed description of how the breakdown voltage is calculated from the voltage of the maximum power under the standard illuminance has been described in detail in the foregoing paragraphs (for example, the embodiment in FIG. 2), and thus will not be described herein. In the solar photovoltaic system 5 of FIG. 6, it is possible to quickly and easily determine which solar cell arrays are abnormal by the displays of the light-emitting diodes of different light-emitting modules.

For example, assuming that some of the solar cells in the solar cell array 50c are abnormal, the dropping of the output voltage V3 provided by the solar cell array 50c results in the reverse bias voltage supplied to the Zener diode 541c to fail to reach the corresponding breakdown voltage. While the other solar cell arrays 50a and 50b are all operating normally, the each of the output voltages V1 and V2 individually provided can supply the Zener diode 541c to reach the reverse bias voltage of the breakdown voltage. At the moment, both of the Zener diodes 541a and 541b are turned on to make the light-emitting diodes 543a and 543b illuminate, while the Zener diode 541c is not turned on and the light-emitting diode 543c fails to illuminate. Therefore, the user can quickly realize which solar cell arrays are abnormal, and perform subsequent corresponding maintenance.

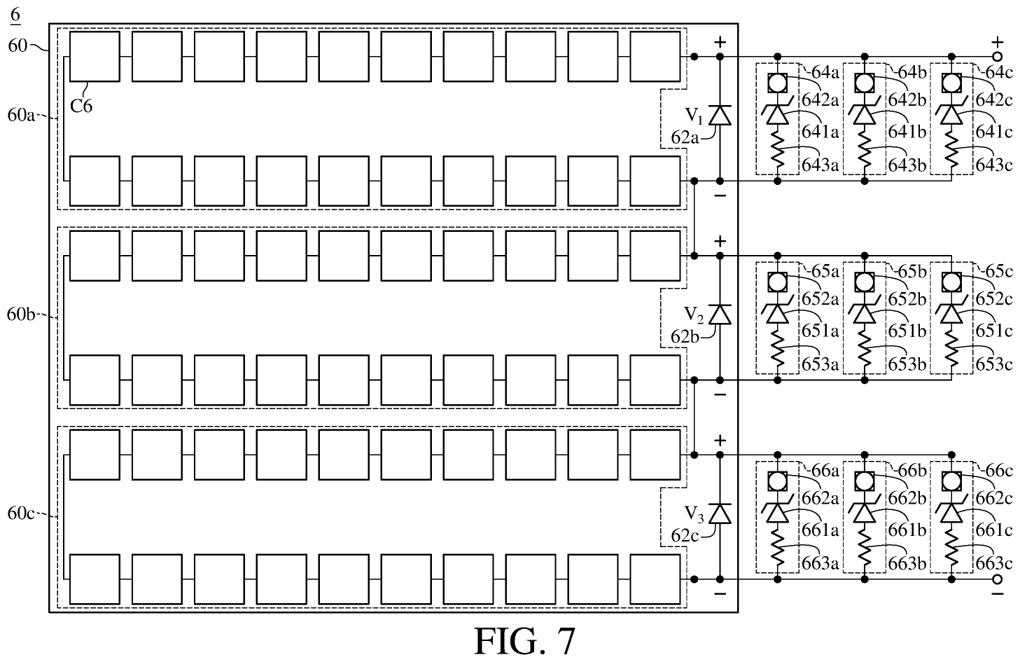

Please refer to FIG. 7. FIG. 7 is a schematic circuit diagram of a solar photovoltaic system according to another embodiment of the present disclosure. As shown in FIG. 7, the solar photovoltaic system 6 includes a solar module 60 and a plurality of light-emitting modules 64a-64c, 65a-65c, and 66a-66c. The solar module 60 includes a plurality of solar cell arrays 60a, 60b, and 60c and a plurality of bypass diodes 62a, 62b, and 62c. The light-emitting modules 64a to 64c include Zener diodes 641a, 641b, and 641c and light-emitting diodes 642a, 642b, and 642c, respectively. The light-emitting modules 65a to 65c include Zener diodes 651a, 651b, and 651c and light-emitting diodes 652a, 652b, and 652c, respectively. The light-emitting modules 66a to 66c include Zener diodes 661a, 661b, and 661c and light-emitting diodes 662a, 662b, and 662c, respectively.

Each solar cell array is connected in parallel with a corresponding bypass diode and a light-emitting module. The solar cell arrays 60a, 60b, and 60c have their positive terminals (+) and a negative terminals (−), respectively, and respectively provide output voltages V1, V2, and V3. The positive terminal and the negative terminal of the solar cell array 60a are electrically connected to the cathodes and the anodes of the Zener diodes 641a, 641b, and 641c, respectively. The positive terminal and the negative terminal of the solar cell array 60b are electrically connected to the cathodes and the anodes of the Zener diodes 651a, 651b, and 651c, respectively. The positive terminal and the negative terminal of the solar cell array 60a are electrically connected to the cathodes and the anodes of the Zener diodes 661a, 661b, and 661c, respectively. Similar to the foregoing embodiments, the light-emitting modules 64a-64c, 65a-65c, and 66a-66c in the solar photovoltaic system 6 of FIG. 7 may include current-limiting resistors 643a-643c, 653a-653c, and 663a-663c. The current-limiting resistors 643a-643c, 653a-653c, and 663a-663c are respectively connected in series to the corresponding light-emitting diodes.

Comparing to the embodiment of FIG. 6, the solar photovoltaic system 6 of the embodiment in FIG. 7 can individually detect the degree of failure for a single solar cell array. For example, assuming that the solar cell array 60c is abnormal, the output voltage V3 provided cannot make the reverse bias voltage supplied to the Zener diodes 661a to 661c reach the corresponding breakdown voltage. At the moment, none of the light-emitting diodes 662a, 662b, and 662c illuminates. By visually observing or using a drone with a camera, the user can determine that the abnormality of the solar cell array 60c is quite serious. If necessary, the abnormal solar cell array can be repaired immediately.

In summary, in the solar photovoltaic system provided by the present disclosure, the voltage of the maximum power of the solar cell array under a standard illuminance is analyzed to select a Zener diode with an appropriate specification. The Zener diode together with the light-emitting diodes are used in the solar module. The element characteristics of the Zener diode are used to selectively turn on the system loop according to the voltage provided by the solar module to make the light-emitting diodes illuminate, thereby achieving failure detection of the solar module.

It will be apparent to those skilled in the art that various modifications and variations can be made to the structure of the disclosed embodiments. It is intended that the specification and examples be considered as exemplars only, with a true scope of the disclosure being indicated by the following claims and their equivalents.

What is claimed is:

1. A solar photovoltaic system, comprising:
a solar cell array having a positive terminal and a negative terminal;
a bypass diode connected to the solar cell array in parallel; and
a light-emitting module connected to the solar cell array in parallel, comprising:
a Zener diode having an anode and a cathode, wherein the cathode of the Zener diode is electrically connected to the positive terminal of the solar cell array while the anode of the Zener diode is electrically connected to the negative terminal of the solar cell array; and
a light-emitting diode connected to the Zener diode in series;
wherein the light-emitting module has a threshold voltage which is a breakdown voltage of the Zener diode and is less than a voltage of a maximum power of the solar cell array under a test condition.

2. The solar photovoltaic system according to claim 1, wherein the light-emitting module comprises a current-limiting resistor connected to the light-emitting diode in series.

3. The solar photovoltaic system according to claim 1, wherein the light-emitting module is a first light-emitting module, the Zener diode and the light-emitting diode of the light-emitting module are a first Zener diode and a first light-emitting diode, respectively, and the solar photovoltaic system further comprises a second light-emitting module comprising:
a second Zener diode having an anode and a cathode, wherein the cathode of the second Zener diode is electrically connected to the positive terminal of the solar cell array while the anode of the second Zener diode is electrically connected to the negative terminal of the solar cell array; and
a second light-emitting diode connected to the second Zener diode in series;
wherein the second light-emitting module has a threshold voltage which is different from the threshold voltage of the first light-emitting module, wherein the threshold voltage of the second light-emitting module is a breakdown voltage of the second Zener diode.

4. The solar photovoltaic system according to claim 3, wherein the first light-emitting module comprises a first current-limiting resistor while the second light-emitting module comprises a second current-limiting resistor, wherein the first current-limiting resistor is connected to the first light-emitting diode in series while the second current-limiting resistor is connected to the second light-emitting diode in series.

5. A solar photovoltaic system, comprising:
a solar photovoltaic module having a positive terminal and a negative terminal, and including:
a plurality of solar cell arrays; and
a plurality of bypass diodes, wherein each of the bypass diodes is connected to a corresponding solar cell of the solar cell arrays in parallel;
a light-emitting module connected to the solar photovoltaic module in parallel, wherein the light-emitting module includes:
a Zener diode having an anode and a cathode, wherein the cathode of the Zener diode is electrically connected to the positive terminal of the solar photovoltaic module while the anode of the Zener diode is electrically connected to the negative terminal of solar photovoltaic module; and
a light-emitting diode connected to the Zener diode in series;
wherein the light-emitting module has a threshold voltage which is a breakdown voltage of the Zener diode and is less than a voltage of a maximum power of the solar cell arrays under a test condition.

6. The solar photovoltaic system according to claim 5, wherein the light-emitting module comprises a current-limiting resistor connected to the light-emitting diode in series.

7. The solar photovoltaic system according to claim 5, wherein the light-emitting module is a first light-emitting module, the Zener diode and the light-emitting diode of the light-emitting module are a first Zener diode and a first light-emitting diode, respectively, and the solar photovoltaic system further comprises a second light-emitting module comprising:
a second Zener diode having an anode and a cathode, wherein the cathode of the second Zener diode is electrically connected to the positive terminal of the solar cell module while the anode of the second Zener diode is electrically connected to the negative terminal of the solar cell module; and
a second light-emitting diode connected to the second Zener diode in series;
wherein the second light-emitting module has a threshold voltage which is different from the threshold voltage of the first light-emitting module, wherein the threshold voltage of the second light-emitting module is a breakdown voltage of the second Zener diode.

8. The solar photovoltaic system according to claim 7, wherein the first light-emitting module comprises a first current-limiting resistor while the second light-emitting module comprises a second current-limiting resistor, wherein the first current-limiting resistor is connected to the first light-emitting diode in series while the second current-limiting resistor is connected to the second light-emitting diode in series.

9. A solar photovoltaic system, comprising:
a plurality of solar cell arrays, wherein each of the plurality of solar cell arrays has a positive terminal and a negative terminal;
a plurality of bypass diodes, wherein each of the bypass diodes is connected to a corresponding solar cell array of the solar cell arrays in parallel;
a plurality of light-emitting modules, wherein each of the light-emitting modules is connected to a corresponding solar cell array of the plurality of solar cell arrays in parallel, wherein each light-emitting module comprises:
a Zener diode having an anode and a cathode, wherein the cathode of the Zener diode is electrically connected to the positive terminal of the corresponding solar cell array while the anode of the Zener diode is electrically connected to the negative terminal of the corresponding solar cell array; and
a light-emitting diode connected to the Zener diode in series;
wherein the light-emitting module has a threshold voltage which is a breakdown voltage of the Zener diode and is less than a voltage of a maximum power of the corresponding solar cell array under a test condition.

10. The solar photovoltaic system according to claim 9, wherein said each of the light-emitting modules comprises a current-limiting resistor connected to the light-emitting diode in series.

11. The solar photovoltaic system according to claim 9, wherein said each of the light-emitting modules is a first light-emitting module, the Zener diode and the light-emitting diode of said each of the light-emitting modules are a first Zener diode and a first light-emitting diode, respectively, and the solar photovoltaic system further comprises a plurality of second light-emitting modules, wherein each of the second light-emitting modules comprises:
a second Zener diode having an anode and a cathode, wherein the cathode of the second Zener diode is electrically connected to the positive terminal of the corresponding solar cell array while the anode of the second Zener diode is electrically connected to the negative terminal of the corresponding solar cell array; and
wherein said each of the second light-emitting modules has a threshold voltage which is different from the threshold voltage of said each of the first light-emitting modules, wherein the threshold voltage of said each of the second light-emitting modules is a breakdown voltage of the corresponding second Zener diode and is less than a voltage of a maximum power of the corresponding solar cell array under a test condition.

12. The solar photovoltaic system according to claim 12, wherein said each of the first light-emitting modules comprises a first current-limiting resistor while said each of the second light-emitting modules comprises a second current-limiting resistor, wherein the first current-limiting resistor is connected to the first light-emitting diode in series while the second current-limiting resistor is connected to the second light-emitting diode in series.
